(19) United States
(12) Patent Application Publication
(10) Pub. No.: US 2026/0203006 A1
(43) Pub. Date: Jul. 16, 2026

(54) PORTABLE INFORMATION CONVERSION DEVICE

(71) Applicant: Goertek Technology Co., Ltd., Qingdao (CN)

(72) Inventors: Ruicong Xiao, Shandong (CN); Xiaofei Zhou, Shandong (CN); Lichao Chen, Shandong (CN); Chuanqi Wang, Shandong (CN); Liang Zhang, Shandong (CN); Peng Guan, Shandong (CN); Xitong Yin, Shandong (CN); Shuangshuai Zhu, Shandong (CN)

(73) Assignee: Goertek Technology Co., Ltd., Qingdao (CN)

(21) Appl. No.: 19/246,081

(22) Filed: Jun. 23, 2025

(30) Foreign Application Priority Data
Nov. 28, 2024 (CN) 202411744798.0

(51) Int. Cl. G06F 3/14; G06F 40/58; H05K 5/00; H05K 5/02

(52) U.S. Cl. CPC G06F 3/1454; G06F 40/58; H05K 5/0086; H05K 5/0217

(57) ABSTRACT

The present disclosure provides a portable information conversion device configured for signal communication with a terminal including a housing and a second screen provided on the housing. The portable information conversion device includes a main body, a first screen, a communication part and a connecting part. The communication part is configured to form a signal communication with the terminal so that the first screen interacts with the terminal and displays information; the connecting part is configured to detachably connect the main body to the housing, and the first screen and the second screen are configured for facing different directions.

### CROSS-REFERENCE TO RELATED APPLICATIONS

The present disclosure claims priority to Chinese Patent Application No. 202411744798.0, filed on Nov. 28, 2024, which is hereby incorporated by reference in its entirety.

### TECHNICAL FIELD

The present disclosure relates to the technical field of electronic devices, and particularly to a portable information conversion device.

### BACKGROUND

In environments such as conferences and multilingual communication, language differences often pose communication barriers among individuals. In various scenarios including work, teaching, and construction projects, users operating their smartphones or dedicated electronic terminals may also need to present certain images or information to the other party with whom they are engaging in face-to-face interaction.

To address this need, users typically rely on two separate devices-a translation device and a terminal—to either translate or display information from the terminal for the other party. At present, users commonly hold the translation device manually or place it on a desk for presentation, which leads to various inconveniences in both operation and portability.

### SUMMARY

In view of the aforementioned disadvantages of the prior art, it is an object of the present disclosure to provide a new type of portable information conversion device.

According to an aspect of the present disclosure, a portable information conversion device is provided, which is configured to be capable of signal communication with a terminal, and the terminal includes a housing and a second screen provided on the housing.

The portable information conversion device includes:
a main body;
a first screen and a communication part, the first screen being provided on the main body, the communication part being provided on the main body, the communication part being configured to form a signal communication with the terminal so that the first screen is capable of establishing interaction with the terminal and realizing display of information; and
a connecting part, the connecting part being provided on the main body and configured to detachably connect the main body to the housing, and the first screen and the second screen being capable of facing different directions.

Optionally, the main body includes a first main body and a second main body which are movably connected, the first screen is provided on the first main body, the connecting part is provided on the second main body, and the connecting part is configured to connect the second main body to the housing.

Optionally, the first main body and the second main body are slidably connected;
or, the main body further includes a rotating shaft, and the first main body and the second main body are rotatably connected via the rotating shaft.

Optionally, the main body includes a first part and a second part which are connected, the first screen is provided on the first part, and the second part is provided with an accommodation slot which forms the connecting part and is configured for connection to the housing.

Optionally, the first part and the second part are foldably connected, such that the portable information conversion device is capable of switching between an unfolded state and a folded state; and
when the portable information conversion device is in the unfolded state, the first screen and the second screen are capable of facing the same direction; when the portable information conversion device is in the folded state, the first screen and the second screen are capable of facing different directions.

Optionally, the connecting part is a magnetic attachment member, and the portable information conversion device is capable of being magnetically attached to the housing via the magnetic attachment member.

Optionally, the connecting part is a hanging slot, and the portable information conversion device is capable of hanging on the housing via the hanging slot.

Optionally, a multilingual processing module and a functional part are further included, the main body is provided with the multilingual processing module and the functional part, the multilingual processing module is in signal communication with the communication part, and the functional part includes at least one of a switch, an indicator, and a microphone.

Optionally, a battery is further included, which is provided on the main body and is configured to supply power to the portable information conversion device.

Optionally, a charging port is further included, the main body being provided with the charging port, and the battery being chargeable through the charging port;
or, a first coil is further included, which is provided on the main body, is electrically connected to the battery, and is capable of adapting to a second coil in the terminal to enable wireless charging.

Optionally, the main body further includes a solar charging part, which is configured to charge the terminal.

A technical effect of the embodiment of the present disclosure lies in that:

The portable information conversion device includes a main body, a first screen, a communication part and a connecting part; the first screen is provided on the main body, the communication part is provided on the main body, the communication part is configured to form a signal communication with the terminal so that the first screen is capable of establishing interaction with the terminal and realizing display of information; the connecting part is provided on the main body and configured to detachably connect the main body to the housing, and the first screen and the second screen are capable of facing different directions. In this way, the connecting part allows the main body to be removably attached to the terminal's housing, facilitating quick and simple assembly between the portable information conversion device and the terminal, thereby forming an integrated electronic device that is convenient for users to carry and use. When standalone use of the portable information conversion device is required, it can be easily detached from the terminal's housing, offering flexibility across various application scenarios.

Other features and advantages of the present disclosure will become apparent from the following detailed description of exemplary embodiments of the present disclosure with reference to the accompanying drawings.

### BRIEF DESCRIPTION OF THE DRAWINGS

The accompanying drawings, which constitute a part of the description, illustrate embodiments of the present disclosure and, together with the description thereof, serve to explain the principles of the present disclosure.

FIG. 1 is a schematic diagram of a connection state of a portable information conversion device with a terminal according to an embodiment of the present disclosure;

FIG. 2 is another schematic diagram of a connection state of a portable information conversion device with a terminal according to an embodiment of the present disclosure;

FIG. 3 is a schematic diagram of a first type of portable information conversion device according to an embodiment of the present disclosure;

FIG. 4 is a state schematic diagram of a second type of portable information conversion device according to an embodiment of the present disclosure;

FIG. 5 is another state schematic diagram of the second type of portable information conversion device according to an embodiment of the present disclosure;

FIG. 6 is another schematic diagram of the first type of portable information conversion device according to an embodiment of the present disclosure;

FIG. 7 is yet another schematic diagram of the first type of portable information conversion device according to an embodiment of the present disclosure;

FIG. 8 is a schematic diagram of a portable information conversion module according to an embodiment of the present disclosure;

FIG. 9 is a schematic diagram of a connection state of a magnet with a terminal according to an embodiment of the present disclosure;

FIG. 10 is a schematic diagram of a magnet according to an embodiment of the present disclosure;

FIG. 11 is another schematic diagram of a connection state of a portable information conversion device with a terminal according to an embodiment of the present disclosure.

### DESCRIPTION OF REFERENCE SIGNS

100, portable information conversion device; 200, terminal; 300, magnet;
1, main body; 11, first part; 12, second part; 13, first main body; 14, second main body; 2, first screen; 3, connecting part; 4, functional part; 5, charging port.

### DETAILED DESCRIPTION

Various exemplary embodiments of the present disclosure will now be described in detail with reference to the accompanying drawings. It is to be noted that unless otherwise specified, the scope of present disclosure is not limited to relative arrangements, numerical expressions and values of components and steps as illustrated in the embodiments.

Description to at least one exemplary embodiment is for illustrative purpose only, and in no way implies any restriction on the present disclosure or application or use thereof.

Techniques, methods and devices known to those skilled in the prior art may not be discussed in detail; however, such techniques, methods and devices shall be regarded as part of the description where appropriate.

In all the examples illustrated and discussed herein, any specific value shall be interpreted as illustrative rather than restrictive. Different values may be available for alternative examples of the exemplary embodiments.

It is to be noted that similar reference numbers and alphabetical letters represent similar items in the accompanying drawings. In the case that a certain item is identified in a drawing, further reference thereof may be omitted in the subsequent drawings.

The embodiment of the present disclosure provides a portable information conversion device 100, which may be in signal communication with a terminal 200 such as a mobile phone, a tablet computer, a notebook computer, or a desktop computer. Herein, the portable information conversion device 100 is provided with a first screen 2 therein, and the first screen 2 may be in signal communication with a second screen of the terminal 200, so as to extend the display function of the terminal 200 and to facilitate the electronic device having the portable information conversion device 100 to be able to adapt to various application scenarios.

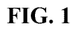

As shown in FIGS. 1 to 7, the portable information conversion device 100 provided by the embodiment of the present disclosure includes:
a main body 1;
a first screen 2 and a communication part, the first screen 2 being provided on the main body 1, the communication part being provided on the main body 1, the communication part being configured to form a signal communication with the terminal 200 so that the first screen 2 is capable of establishing interaction with the terminal 200 and realizing display of information;
a connecting part 3, the connecting part 3 being provided on the main body 1 and configured to detachably connect the main body 1 to the housing, and the first screen 2 and the second screen being capable of facing different directions.

Specifically, the main body 1 may be made of lightweight yet robust materials, such as aluminum alloy or carbon fiber, to ensure the durability and portability of the portable information conversion device 100. The shape and size design of the main body 1 may be adjusted based on the type of connected terminal 200 and the usage scenario. For example, it may be designed in the form of a cube, cylinder, or other shapes to facilitate convenient assembly of the portable information conversion device 100 with the housing of the terminal 200.

As shown in FIGS. 1 to 3, the first screen 2 is located on one side of the main body 1, typically on the side of the main body 1 that is away from the terminal 200, to facilitate image display on the first screen 2. Herein, the first screen 2 may use high-resolution, low-power LCD (Liquid Crystal Display), OLED (Organic Light-Emitting Diode), and ink screen (e-paper display technology), among others. The size of the first screen 2 may be flexibly designed according to requirements to achieve the image extension functionality of the second screen of the terminal 200. The first screen 2 also supports touch operation, so that the user may directly operate on the first screen 2 and control the connected terminal 200.

In the embodiment of the present disclosure, by providing the first screen 2, the portable information conversion device 100 may establish interaction with the terminal 200, achieving synchronized or extended display of the content on the second screen. This function significantly expands the visual workspace for users when working or entertaining with the terminal 200, thereby improving multitasking efficiency, particularly providing users with a more immersive and comfortable visual experience when handling complex documents, watching high-definition videos, or participating in remote meetings.

Herein, the first screen 2 of the portable information conversion device 100 and the second screen of the terminal 200 may face different directions, meaning that both screens may display content outwardly, which facilitates multi-user scenarios and adapts to scenarios such as meetings or teaching. Furthermore, the setup of the first screen 2 also extends the functionality of the second screen of the terminal 200, thereby enhancing the use function of the electronic device comprising the portable information conversion device 100 and the terminal 200.

For instance, when the electronic device comprising the portable information conversion device 100 and the terminal 200 is applied in a meeting scenario, the second screen of the terminal 200 may be used by a host of a party, while the first screen 2 of the portable information conversion device 100 may be viewed by a participant of the other party, which may facilitate the implementation of multitasking. Moreover, by using the multilingual processing module in the portable information conversion device 100, it is possible to translate the textual information displayed on the second screen of the terminal 200, so as to enable the first screen 2 of the portable information conversion device 100 to display information in different languages, further enhancing the user experience of the electronic device.

Herein, the main body 1 is provided a communication part therein. The communication part includes, but is not limited to, Wi-Fi modules, Bluetooth modules, NFC modules, USB interfaces and the like, and is configured to establish wireless or wired connections with the terminal 200, so as to enable signal transmission between the portable information conversion device 100 and the terminal 200, and to achieve real-time synchronization or extension of the second screen of the terminal 200. Additionally, by utilizing the high-speed data transfer capabilities of the communication part, the portable information conversion device 100 may also serve as a data storage and transmission intermediary for the terminal 200, enabling quick backup, transfer, and sharing of files.

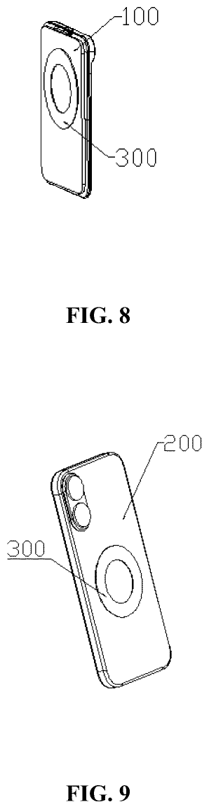

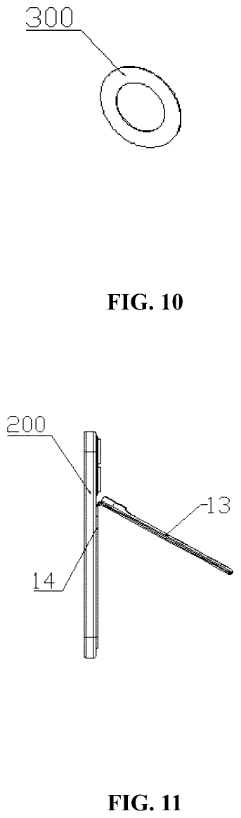

As shown in FIGS. 8 to 10, in one embodiment, magnetic components such as magnets 300 may be provided at the connection point between the main body 1 and the terminal 200 to achieve a quick connection of the main body 1 with the terminal 200 through magnetic attraction.

In another embodiment, a slot that matches a connection protrusion on the terminal 200 may be provided on the main body 1, so as to achieve the connection of the main body 1 with the housing of the terminal 200 through physical insertion.

The design of the connecting part 3 allows the portable information conversion device 100 to easily and quickly connect with the housing of the terminal 200, so that the portable information conversion device 100 is integrated with the terminal 200, which is convenient to carry and use. Whether it is magnetic or slot-based, this greatly simplifies assembly difficulty and enhances convenience. Moreover, the design of the connecting part 3 also enables the portable information conversion device 100 to have wide compatibility, and may be adapted to various types and specifications of housings, such that the portable information conversion device 100 may meet the personalized requirements of different users, and be suitable for use in various scenarios.

Thus, the main body 1 may be detachably connected to the housing of the terminal 200 through methods like magnetism, insertion, or hanging, which may facilitate quick and simple assembly of the portable information conversion device 100 with the terminal 200 to form an integrated electronic device, thereby being convenient for the user to carry and use. When the portable information conversion device 100 needs to be used separately, it may be easily detached from the housing of the terminal 200 to adapt to different application scenarios. Moreover, the detachable connection also allows the reuse of the portable information conversion device 100 to establish interaction with different housings, extending the lifespan and application scope of the portable information conversion device 100.

After connecting the main body 1 to the housing of the terminal 200 via the connecting part 3, users may choose to project some or all of the display content from the second screen of the terminal 200 onto the first screen 2, achieving multitasking or multi-screen viewing experiences suitable for various application scenarios.

Herein, the portable information conversion device 100 may be provided with a battery to provide power to itself, so as to facilitate long-term use of the portable information conversion device 100. Moreover, after establishing a signal communication with the terminal 200 via the communication part, the portable information conversion device 100 may also provide supplementary power to the terminal 200, so as to effectively extend its usage time and address issues of insufficient battery life during long outdoor activities or mobile office work.

In addition, according to user's requirements, additional components such as speakers, microphones, and cameras may be integrated into the portable information conversion device 100 to further enhance the functionality of the terminal 200.

Optionally, the main body 1 includes a first main body 13 and a second main body 14 which are movably connected. The first screen 2 is provided on the first main body 13, and the connecting part 3 is provided on the second main body 14 and configured to connect the second main body 14 to the housing.

Specifically, the main body 1 of the portable information conversion device 100 may consist of two parts: the first main body 13 and the second main body 14. One of the first main body 13 and the second main body 14 is provided with the first screen 2, and the other of the first main body 13 and the second main body 14 is also provided with the connecting part 3, so as to enable the portable information conversion device 100 to be connected to the housing of the terminal 200.

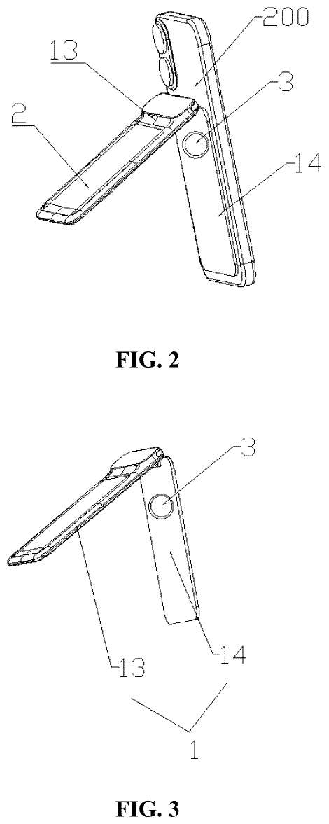

In one embodiment, the first main body 13 and the second main body 14 may be rotatably connected via a rotating shaft, meaning they may rotate relative to the rotating shaft. When the second main body 14 is connected to the housing of the terminal 200 via the connecting part 3, the first main body 13 is capable of rotating and fits with the second main body 14, as shown in FIG. 1, which may be convenient to carry; the first main body 13 is also capable of rotating and forms an angle with the second main body 14, as shown in FIGS. 2 and 11, and at this time, the first main body 13 and the second main body 14 may be used as a support of the terminal 200, so that the terminal 200 may be used in a standing manner without being held by the user, thereby improving the use experience of the user.

In another embodiment, the second main body 14 may be provided with a sliding rail, and the first main body 13 is connected to the sliding rail and may slide along it to change positions, thereby adapting to different application scenarios.

Optionally, the first main body 13 and the second main body 14 are slidably connected;
or, the main body 1 further includes a rotating shaft, and the first main body 13 and the second main body 14 are rotatably connected via the rotating shaft.

In another embodiment, the second main body 14 may be provided with a sliding rail, and the first main body 13 is connected to the sliding rail and may slide along it to change positions, thereby adapting to different application scenarios. For example, a corresponding functional module may be provided on the second main body 14, and the movement of the first main body 13 may be configured to display or hide the functional module; alternatively, the first screen 2 may also be provided on the second main body 14, and the movement of the first main body 13 may be configured to display or hide the first screen 2, and may also provide protection for the first screen 2.

In another embodiment, the first main body 13 and the second main body 14 may be rotatably connected via a rotating shaft, meaning they may rotate relative to the rotating shaft. When the second main body 14 is connected to the housing of the terminal 200 via the connecting part 3, the first main body 13 is capable of rotating and fits with the second main body 14, as shown in FIG. 1, which may be convenient to carry; the first main body 13 is also capable of rotating and forms an angle with the second main body 14, as shown in FIGS. 2 and 11, and at this time, the first main body 13 and the second main body 14 may be used as a support of the terminal 200, so that the terminal 200 may be used in a standing manner without being held by the user, thereby improving the use experience of the user.

Optionally, the first screen 2 is located on the side of the first main body 13 that is farther away from the second main body 14.

As shown in FIG. 2, the second main body 14 is connected to the housing of the terminal 200 through the connecting part 3 thereon, and the first screen 2 is located on one side of the first main body 13 away from the second main body 14, so that the first screen 2 and the second screen of the terminal 200 may face different directions, that is, the two screens may be displayed externally to be convenient for multiple users to use, which may achieve the extension of the second screen of the terminal 200, and also enhance the use function of the electronic device comprising the portable information conversion device 100 and the terminal 200.

Optionally, the main body 1 includes a first part 11 and a second part 12 which are connected, the first screen 2 is provided on the first part 11, and the second part 12 is provided with an accommodation slot which forms the connecting part 3 and is configured for connection to the housing.

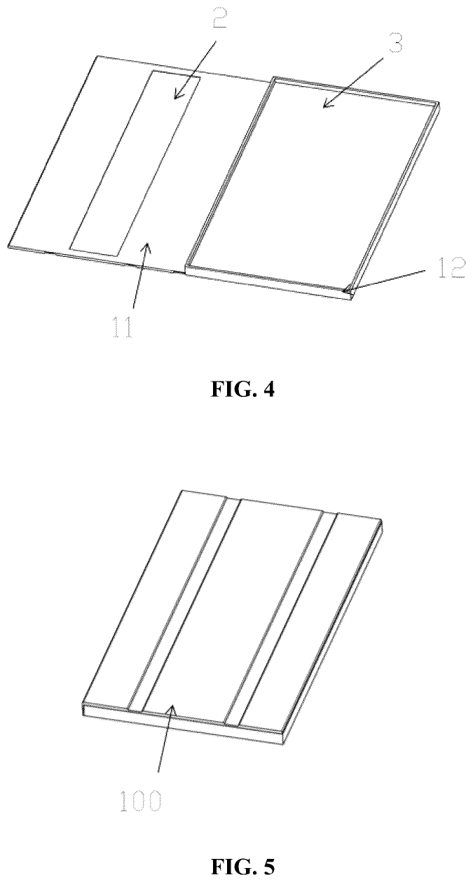

As shown in FIG. 4, the main body 1 of the portable information conversion device 100 may comprise two parts: the first part 11 and the second part 12. One of the first part 11 and the second part 12 is provided with the first screen 2, and the other of the first part 11 and the second part 12 is provided with the connecting part 3, so as to connect the portable information conversion device 100 to the housing of the terminal 200.

Herein, the second part 12 may be provided with an accommodation slot that matches the size and shape of the housing of the terminal 200, so as to mount the housing of the terminal 200 within the accommodation slot and achieve a secure connection between the two. In this way, the main body 1 may serve as a protective case for the terminal 200 to protect the terminal 200, which helps to extend the lifespan of the terminal 200. Herein, the terminal 200 includes but is not limited to smartphones, tablets, and laptops.

Optionally, the first part 11 and the second part 12 are foldably connected, such that the portable information conversion device 100 is capable of switching between an unfolded state and a folded state;
when the portable information conversion device 100 is in the unfolded state, the first screen 2 and the second screen are capable of facing the same direction; when the portable information conversion device 100 is in the folded state, the first screen 2 and the second screen are capable of facing different directions.

FIG. 4 shows the schematic diagram of the portable information conversion device 100 in the unfolded state. At this time, the first part 11 and the second part 12 are on the same horizontal plane, and the first screen 2 may face the same direction as the second screen of the terminal 200, which may increase the total screen area of the electronic device and be convenient for users to use.

At this time, the electronic device comprising the portable information conversion device 100 and the terminal 200 may be suitable for multi-tasking scenarios. For example, in an office environment, users may handle documents on the second screen while checking emails or meeting schedules on the first screen 2; in entertainment scenarios, users may watch movies on the second screen while browsing social media or playing games on the first screen 2; in learning scenarios, users may read textbooks on the second screen while taking notes or searching for information on the first screen 2.

FIG. 5 shows a schematic diagram of the portable information conversion device 100 in the folded state. At this time, when the first part 11 completely covers the second part 12, the first screen 2 may fit with the second screen of the terminal 200. At this time, the electronic device comprising the portable information conversion device 100 and the terminal 200 may be carried and stored as a whole, while protecting the screens from damage and enhancing the safety and durability of the electronic device.

Moreover, the foldable connection between the first part 11 and the second part 12 enables the portable information conversion device 100 to easily switch between the unfolded and folded states, thereby adapting to different application scenarios.

Optionally, the connecting part 3 is a magnetic attachment member, and the portable information conversion device 100 is capable of being magnetically attached to the housing via the magnetic attachment member.

As shown in FIGS. 2 and 3, the connecting part 3 may be made of ferromagnetic metal or magnets, such that the connecting part 3 may have strong magnetic properties for easy connection of the portable information conversion device 100 to the housing of the terminal 200 through a magnetic attraction force. Herein, the terminal 200 includes but is not limited to smartphones, tablets, laptops, and desktop computers. For example, if the housing of the terminal 200 contains a magnet, it may magnetically attract the connecting part 3 and the terminal 200 directly; if the housing of the terminal 200 does not have a magnet, an additional magnet may be added, and the connecting part 3 and the housing of the terminal 200 may be magnetically attracted by the magnet, which may realize the convenient connection of the portable information conversion device 100 with the housing of the terminal 200, thereby reducing the assembly difficulty.

Moreover, the magnetic connecting part may provide stable connectivity through magnetic force, so as to ensure that the portable information conversion device 100 will not fall off due to accidental collision or shaking during application. The property of the magnetic connection also enables the connecting part 3 to adapt to the connection requirements of different angles and directions while maintaining the reliability of the connection, thereby improving the stability of the electronic device comprising the portable information conversion device 100 and the terminal 200.

In addition, the user may magnetically connect the portable information conversion device 100 to the housing of the terminal 200, or detach the portable information conversion device 100 for carrying independently or performing other operations according to actual needs, thereby enhancing the flexibility of use.

Optionally, the connecting part 3 is a hanging slot, and the portable information conversion device 100 is capable of hanging on the housing via the hanging slot.

Specifically, the connecting part 3 may be a hanging slot provided on the main body 1, which may be hung on the housing of the terminal 200 and achieve convenient connection between the portable information conversion device 100 and the terminal 200. The design of the hanging slot allows the user to easily hang the portable information conversion device 100 on the housing of the terminal 200 without any tools or additional accessories. This plug-and-play connection method greatly simplifies the operation process, which enables the user to quickly complete the connection, thereby improving convenience of use. Herein, the terminal 200 includes but is not limited to laptops, desktops, and TVs.

Herein, the tight fit between the hanging slot and the housing of the terminal 200 also ensures that the portable information conversion device 100 will not accidentally fall off or loosen during connection, enhancing the stability of the electronic device comprising the portable information conversion device 100 and the terminal 200, and also ensuring the safety of the user during use. Moreover, through the hanging slot-based connection, the user may hang or remove the portable information conversion device 100 at any time according to needs, thereby flexibly adjusting the use space and further meeting the use requirements in different scenarios.

Optionally, the communication part includes at least one of a Bluetooth module and an NFC module.

Specifically, in one embodiment, the communication part may include the Bluetooth module, such that the portable information conversion device 100 may establish wireless connection with the terminal 200, which may not only avoid the constraints of data cables, but also make data transmission and pairing between devices more flexible and convenient. The Bluetooth-connected portable information conversion device 100 may also be detached from the housing of the terminal 200 for independent use, adapting to different application scenarios. The user may easily synchronize data, transfer files, or remotely control devices in any Bluetooth-supported environment.

In another embodiment, the communication part may be provided to include an NFC module, such that the portable information conversion device 100 can be rapidly paired with the terminal 200 which also supports NFC through the near field communication technology. This pairing method is not only easy to operate, which can be accomplished by simply bringing the two devices close together, but also provides a high level of security.

In yet another embodiment, the communication part may be provided to include both Bluetooth and NFC modules, and the Bluetooth module or the NFC module may be matched for communication according to a distance between the portable information conversion device 100 and the terminal 200 or a communication requirement, which may improve the flexibility of signal communication and facilitate the application of different application scenarios. Moreover, it is also possible to reduce production costs and assembly difficulty without designing connection lines again.

Optionally, a multilingual processing module and a functional part 4 are further included, the main body 1 is provided with the multilingual processing module and the functional part 4, the multilingual processing module is in signal communication with the communication part, and the functional part 4 includes at least one of a switch, an indicator, and a microphone.

Specifically, the main body 1 may be embedded with a multilingual processing module, which is in signal communication with the communication part, such that the multilingual processing module may translate the text information displayed on the second screen of the terminal 200, so that the first screen 2 of the portable information conversion device 100 may display information in different languages, enabling it to be used in scenarios such as multilingual meeting and multilingual teaching, and also improves the use experience of electronic equipment.

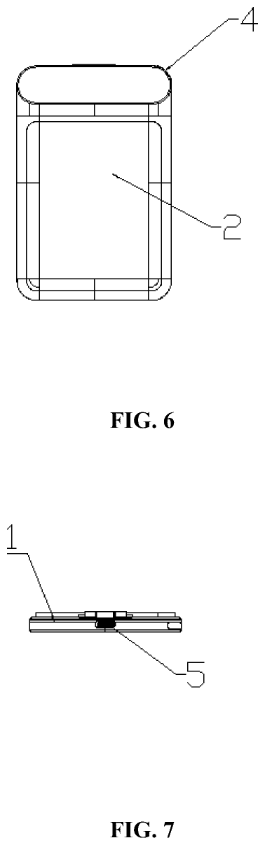

As shown in FIG. 6, the main body 1 may also include functional parts 4 such as switches, indicators, and microphones to expand the functionality of the portable information conversion device 100. Herein, the switches, which may include but not limited to mechanical buttons or touch electrodes, are configured to turn the portable information conversion device 100 on and off. Indicators include but are not limited to indicator lights or sounders, and are configured to provide visual or auditory feedback indicating that the portable information conversion device 100 is operational. Microphones may record audio information from the terminal 200, facilitating storage and use.

Additionally, the main body 1 may be embedded with a circuit board that integrates signal transmission lines and necessary electronic components for transferring images, videos, and audio signals between the second screen and the first screen 2. These signals may be either analog or digital, depending on the design requirements of the portable information conversion device 100. Herein, the circuit board could be a printed circuit board (PCB) or a flexible printed circuit (FPC).

In addition, to ensure synchronous content display on both screens, the portable information conversion device 100 may be provided with a control module. This control module may communicate with both screens via the circuit board, and control their display content and methods based on user's operations or preset display modes, so as to ensure the controllability of the portable information conversion device 100.

Optionally, a battery is further included, which is provided on the main body 1 and is configured to supply power to the portable information conversion device 100.

Specifically, the battery serves as the power source for the portable information conversion device 100, which determines the operational duration and usage range of the portable information conversion device 100. The battery may supply power to the first screen 2 and the functional parts 4 to ensure they function properly. By providing the battery into the main body 1, not only is it possible to make full use of the own space of the body 1, but it is also possible to ensure that the battery capacity is maximized, thereby enhancing the endurance of the portable information conversion device 100.

Optionally, a charging port 5 is further included, the main body 1 being provided with the charging port 5, and the battery being chargeable through the charging port 5;
or, a first coil is further included, which is provided on the main body 1, is electrically connected to the battery, and is capable of adapting to a second coil in the terminal 200 to enable wireless charging.

As shown in FIG. 7, in one embodiment, the setting of the charging port 5 allows the user to conveniently charge the battery using an external power adapter or charging device without needing to disassemble the device or find specific charging environments. This design not only improves the convenience of charging, but also reduces the problem of limited use of the portable information conversion device 100 due to inconvenient charging.

Moreover, by charging the battery through the charging port 5, it is possible to ensure that the portable information conversion device 100 may be promptly recharged when its power is depleted, thereby extending the usage time of the portable information conversion device 100. This is particularly important for the user who needs to use the portable information conversion device 100 for a long period of time, and may significantly enhance their user experience and work efficiency.

In another embodiment, it is possible to use the first coil integrated in the portable information conversion device 100 and the second coil in the terminal 200 to realize wireless charging based on the principle of electromagnetic induction, and the user does not need to find and insert the charging cable, but only needs to place the portable information conversion device 100 in the terminal 200 that supports wireless charging to start charging, which greatly improves the convenience of charging and also reduces the energy loss during the charging process, thus improving the charging efficiency.

Herein, the wireless charging method avoids the problems such as entanglement and damage that may be caused by the traditional charging cable, such that the charging process of the portable information conversion device 100 is more neat and efficient, and also such that the connection between the portable information conversion device 100 and the housing of the terminal 200 is more compact, thereby improving the space utilization. Moreover, the first coil is integrated directly inside the body 1 without the need for additional charging ports or space, which helps to save the space occupied by the portable information conversion device 100.

In addition, the wireless charging module is typically equipped with an intelligent charging management system, which may monitor the battery status in real-time, prevent overcharging, over-discharging and other safety issues, and ensure the safety and reliability of the portable information conversion device 100 in the charging process.

Optionally, the main body 1 further includes a solar charging part, which is configured to charge the terminal 200.

Specifically, the solar charging part of the main body 1 may be charged by using solar energy, so that the portable information conversion device 100 may autonomously obtain electric energy outdoors or in an environment with sufficient light, which reduces reliance on the conventional power grid, helps to reduce carbon emissions and environmental pollution, and may also reduce the overall energy consumption of the portable information conversion device 100.

In addition, in the case of unstable power supply or power failure, the solar charging part may also be used as an emergency charging means, and provide continuous power support for the terminal 200 through the principle of electromagnetic induction, so that the user does not need to worry about the problem of insufficient power of the terminal 200, thereby improving the use experience of the user and also helping the terminal 200 to be able to be used in extreme environments.

The embodiment of the present disclosure also provides a portable information conversion module that includes a magnet 300 and the portable information conversion device 100. One side of the magnet 300 is connected magnetically to the connecting part 3, while the other side of the magnet 300 is connected magnetically to the housing.

Specifically, the portable information conversion device 100 is provided with a connecting part 3 such as a ferromagnetic metal member or a magnet member, that is, the connecting part 3 may have a good magnetic property. The magnetic connection between the connecting part 3 and the housing of the terminal 200 may be realized by using both sides of the magnet 300, thereby realizing a convenient connection of the portable information conversion module with the housing of the terminal 200 and reducing the assembly difficulty.

Moreover, it is possible to provide stable connectivity through magnetic force, so as to ensure that the portable information conversion device 100 will not fall off due to accidental collision or shaking during application. The property of the magnetic connection also enables the portable information conversion module to adapt to the connection requirements of different angles and directions while maintaining the reliability of the connection, thereby improving the stability of the electronic device comprising the portable information conversion module and the terminal 200.

The embodiment of the present disclosure further provides an electronic device, as shown in FIG. 2, which includes the terminal 200 and the portable information conversion device 100. The portable information conversion device 100 is connected to the housing via the connecting part 3, thereby forming an integrated electronic device that is convenient for carrying and use;

Alternatively, as shown in FIGS. 8 and 9, the terminal 200 and the portable information conversion module are included. The portable information conversion module is connected to the housing via the magnet 300, forming an integrated electronic device that is convenient for carrying and use.

Herein, the first screen 2 of the portable information conversion device 100 and the second screen of the terminal 200 may face different directions, meaning that both screens may display content outwardly, which facilitates multi-user use, enabling the second screen of the terminal 200 to be extended, and also enhancing the use function of the electronic device comprising the portable information conversion device 100 and the terminal 200.

The above embodiments primarily highlight the differences between the various embodiments. As long as no contradictions arise, the distinct optimization features between the various embodiments may be combined to form refined or improved embodiments. For the sake of brevity, such combinations will not be elaborated further herein.

Although some specific embodiments of the present disclosure have been described in detail by way of examples, it is understood by those skilled in the art that these examples are for illustrative purposes only and are not intended to limit the scope of the present disclosure. Those skilled in the art should understand that modifications to the above embodiments may be made without departing from the scope or spirit of the present disclosure. The scope of the present disclosure is ultimately defined by the appended claims.

1. A portable information conversion device, configured for a signal communication with a terminal comprising a housing and a second screen provided on the housing, the portable information conversion device comprising:
a main body;
a first screen and a communication part provided on the main body, the communication part configured to form a signal communication with the terminal so that the first screen interacts with the terminal and displays information, and the first screen and the second screen configured for facing at least different directions; and
a connecting part provided on the main body and configured to detachably connect the main body to the housing.

2. The portable information conversion device according to claim 1, wherein the main body comprises a first main body and a second main body which are movably connected to each other, the first screen is provided on the first main body, the connecting part is provided on the second main body, and the connecting part is configured to connect the second main body to the housing.

3. The portable information conversion device according to claim 2, wherein the first main body and the second main body are slidably connected; or
the main body further comprises a rotating shaft, and the first main body and the second main body are rotatably connected via the rotating shaft.

4. The portable information conversion device according to claim 1, wherein the main body comprises a first part connected to a second part, the first screen is provided on the first part, and the second part is provided with an accommodation slot which forms the connecting part configured for a connection to the housing.

5. The portable information conversion device according to claim 4, wherein the first part and the second part are foldably connected to each other, such that the portable information conversion device is adapted to switch between an unfolded state and a folded state; and
when the portable information conversion device is in the unfolded state, the first screen and the second screen are further adapted to face the same direction; when the portable information conversion device is in the folded state, the first screen and the second screen are adaptable to face different directions.

6. The portable information conversion device according to claim 1, wherein the connecting part comprises a magnetic attachment member, such that the portable information conversion device is configured for magnetic attachment to the housing.

7. The portable information conversion device according to claim 1, wherein the connecting part comprises a hanging slot, such that the portable information conversion device is configured to hang on the housing.

8. The portable information conversion device according to claim 1, further comprising a multilingual processing module and a functional part, the main body is provided with the multilingual processing module and the functional part, the multilingual processing module is in a signal communication with the communication part, and the functional part comprises at least one of a switch, an indicator, and a microphone.

9. The portable information conversion device according to claim 1, further comprising a battery, which is provided on the main body and is configured to supply power to the portable information conversion device.

10. The portable information conversion device according to claim 9,
further comprising a charging port, the main body being provided with the charging port, and the battery being chargeable through the charging port; or
further comprising a first coil, which is provided on the main body and is electrically connected to the battery, thereby adapted to a second coil in the terminal for wireless charging.

11. The portable information conversion device according to claim 10, wherein the main body further comprises a solar charging part configured to charge the terminal.
